(19) United States
(12) Patent Application Publication
(10) Pub. No.: US 2004/0195624 A1
(43) Pub. Date: Oct. 7, 2004

(54) Strained silicon fin field effect transistor

(75) Inventors: Chee-Wee Liu, Taipei (TW); Shu-Tong Chang, Taipei (TW); Shi-Hao Hwang, Taipei (TW)

Correspondence Address: BEVER HOFFMAN & HARMS, LLP, TRI-VALLEY OFFICE, 1432 CONCANNON BLVD., BLDG. G, LIVERMORE, CA, 94550, US

(73) Assignee: National Taiwan University, Taipei (TW)

(21) Appl. No.: 10/785,515

(22) Filed: Feb. 24, 2004

(30) Foreign Application Priority Data
Apr. 4, 2003 (TW) 92107789

(51) Int. Cl. H01L 21/336; H01L 27/01; H01L 27/12; H01L 31/0392

(52) U.S. Cl. 257/347

(57) ABSTRACT

Strained Si surrounding the SiGe embedded body on a SOI (silicon on insulator) substrate forms a novel FinFET. The mobility in the channel is enhanced due to strain of the Si channel. The strained Si FinFET includes a SOI substrate, an SiGe embedded body, a strained Si channel surrounding layer, an oxide layer, a poly Si gate electrode (or metal gate electrode), a source and a drain.

### FIELD OF THE INVENTION

This invention relates to a field effect transistor, and more particularly to a field effect transistor applied to solve the problems concerning physics limitations caused by scaling down of device dimensions. This invention can improve device integration, driving current, and operating speed.

### BACKGROUND OF THE INVENTION

One advantage of the FinFET (Fin Field Effect Transistor) is that the channel has not to be doped, which is a very important property when the transistor is scaling down. That is to say, the channel without doping gives the gate higher ability to control threshold voltage. Another advantage of the FinFET is that the “Fin” can be so narrow that the whole fin area is controlled by the gate. When the device is turned off, there is no path for carriers to move from source to drain. Therefore, there is no leakage current and the power dissipation is very small.

In the metal oxide semiconductor field effect transistor (MOSFET) which is made of strained Si, it is proved that mobilities of electron and hole are higher than those of conventional MOSFET. Currently, the method for manufacturing strained Si is to deposit a Si layer on a relaxed SiGe buffer layer which can be deposited on a silicon-on-insulator (SOI) substrate, called SGOI (silicon-on-SiGe-on insulator), or on a traditional bulk Si substrate. Both of the two structures have been verified to enhance the operating speed of P-type and N-type MOSFETs. In fact, Intel has applied strained-Si technology to its 90 nm technology node. (It is noted here that: Intel utilizes bulk Si substrate.)

In this invention, strained Si FinFET is designed by combining the advantages of the foresaid two devices. Hence, the transistor provided in the present invention has the characteristics of much smaller device dimensions, enhancement of current driving ability, and breakthrough of physics limitations.

### SUMMARY OF THE INVENTION

The main purpose of the present invention is to provide a strained Si FinFET. The strained Si FinFET can reduce device dimensions and enhance current driving ability so as to break physics limitations.

It is one object of the present invention to provide the industry devices with higher operating speed and to enhance the device performance greatly so that better products with higher efficiency can be produced in the field of integrated circuits.

According to one aspect of the present invention, a strained Si FinFET includes: a substrate, a strained silicon in a shape of a fin island located on the substrate, a semiconductor embedded in the strained silicon, a dielectric layer formed on a surface of an intermediate section of the strained silicon, and electrodes formed on the fin island and the dielectric layer.

Preferably, the substrate is an SOI (Silicon on Insulator) substrate.

Preferably, the semiconductor is employed for generating a strained silicon channel.

Preferably, the semiconductor is selected from a group consisting of a SiGe alloy, a SiGeC alloy, a SiC alloy, and the material which is suitable for producing strained silicon.

Preferably, the surfaces of the intermediate section of the strained silicon covered by the dielectric layer include left side, right side, and top side surfaces of the intermediate section.

Preferably, the dielectric layer is one of an oxide layer and a high dielectric constant (high K) layer.

Preferably, the high dielectric constant (high K) layer is selected from a group consisting of HfO₂, Si₃N₄, and Al₂O₃.

Preferably, the electrodes are a gate electrode formed on a surface of the dielectric layer, a source electrode formed on one terminal of the strained silicon, and a drain electrode formed on the other terminal of the strained silicon.

Preferably, the gate electrode is selected from a group consisting of an n⁺ doped polysilicon gate electrode, a p⁺ doped polysilicon gate electrode, an n⁺ doped poly SiGe gate electrode, a p⁺ doped poly SiGe gate electrode, and a metal gate electrode.

Preferably, the strained silicon has conducting carriers.

Preferably, the conducting carrier is one of an electron and a hole.

According to another aspect of the present invention, a method for manufacturing a strained Silicon FinFET, includes: (a) providing a substrate comprising a first silicon layer thereon, (b) forming a semiconductor layer on the substrate, (c) forming a fin-shaped island, (d) forming a second silicon layer on a surface of the fin-shaped island, (e) forming a dielectric layer on surfaces of the second silicon layer at an intermediate section of the fin-shaped island, and (f) forming electrodes on the dielectric layer and the fin-shaped island.

Preferably, the substrate is an SOI (Silicon on Insulator) substrate.

Preferably, the semiconductor is employed for generating a strained silicon channel.

Preferably, the semiconductor is selected from a group consisting of a SiGe alloy, a SiGeC alloy, a SiC alloy, and a material which is suitable for producing strained silicon.

Preferably, the fin-shaped island includes the semiconductor layer and the first silicon layer.

Preferably, the method for forming the fin-shaped island is etching.

Preferably, the surface of the fin-shaped island covered by the second silicon layer is the whole surface of the fin-shaped island.

Preferably, the dielectric layer is one of an oxide layer and a high dielectric constant (high K) layer.

Preferably, the high dielectric constant (high K) layer is selected from a group consisting of HfO₂, Si₃N₄, and Al₂O₃.

Preferably, the surfaces of the second silicon layer covered by the dielectric layer include left side, right side, and top side surfaces of the second silicon layer.

Preferably, the electrodes are a gate electrode formed on a surface of the dielectric layer, a source electrode formed on one terminal of the fin, and a drain electrode formed on the other terminal of the fin.

Preferably, the gate electrode is selected from a group consisting of an n⁺ doped polysilicon gate electrode, a p⁺ doped polysilicon gate electrode, an n⁺ doped poly SiGe gate electrode, a p⁺ doped poly SiGe gate electrode, and a metal gate electrode.

The foregoing and other features and advantages of the present invention will be more clearly understood through the following descriptions with reference to the drawings, wherein:

### BRIEF DESCRIPTION OF THE DRAWINGS

FIG. 1 is a perspective view of the structure of the strained Si FinFET according to a preferred embodiment of the present invention;

FIG. 2 is a cross-sectional view of the strained Si fin-shaped structure along the line A to A′ of FIG. 1 according to a preferred embodiment of the present invention;

FIG. 3a illustrates a lithography process for fabricating fin-shaped Si and SiGe isolated island according to a preferred embodiment of the present invention;

FIG. 3b shows the etched fin-shaped Si and SiGe isolated island according to a preferred embodiment of the present invention;

FIG. 3c shows the growth of strained Si on the left (region 10), right (region 11), and top (region 12) of the fin-shaped Si and SiGe isolated island according to a preferred embodiment of the present invention;

FIG. 3d shows the growth of oxide layer on the strained Si according to a preferred embodiment of the present invention;

FIG. 3e shows the growth of poly Si gate on the oxide layer according to a preferred embodiment of the present invention;

FIG. 4 shows the effective mobility of carrier in the strained silicon-to-effective electric field in conventional Si FinFET according to the prior art;

FIG. 5 shows the unit cell with relaxed SiGe embedded body according to a preferred embodiment of the present invention;

FIG. 6 shows the increasing factor of mobility of carrier in the strained Si surrounding the relaxed SiGe embedded body-to-mole fraction of Ge of SiGe buffer layer according to a preferred embodiment of the present invention;

FIG. 7 is the unit cell with strained SiGe embedded body according to a preferred embodiment of the present invention; and

FIG. 8 shows the increasing factor of mobility of carrier in the strained Si surrounding the fully-strained SiGe embedded body-to-mole fraction of Ge of SiGe buffer layer according to a preferred embodiment of the present invention.

### DETAILED DESCRIPTION OF THE PREFERRED EMBODIMENT

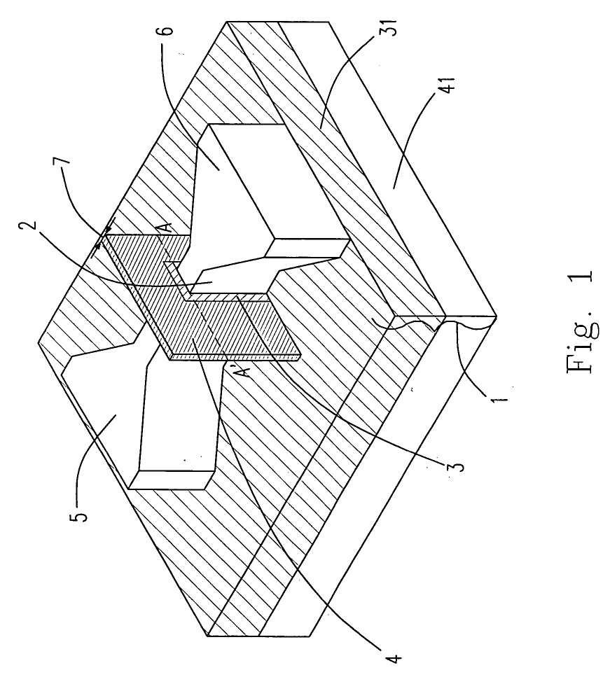

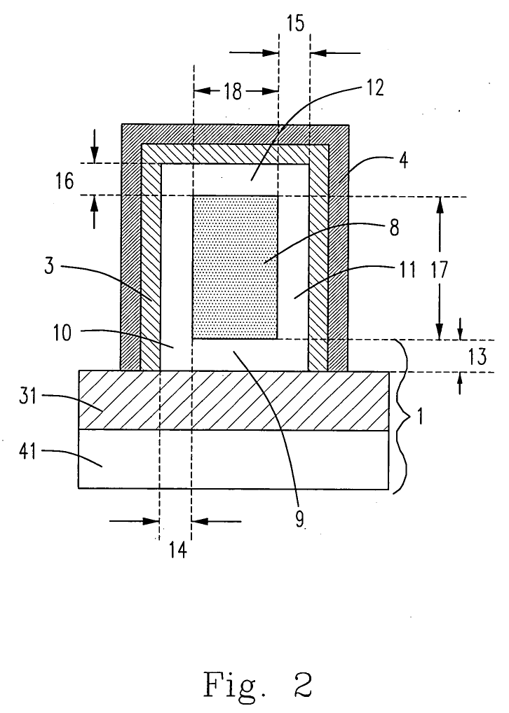

The present invention will now be described more specifically with reference to the following embodiments. FIG. 1 shows the structure of strained Si FinFET. The Si FinFET includes the SOI (silicon on insulator) substrate 1, the strained Si fin 2, the oxide layer 3, the poly Si gate electrode 4, the source electrode 5, and the drain electrode 6. The line A-A′ is the cross section of the strained Si fin 2 which is shown in FIG. 2 along the direction perpendicular to the channel.

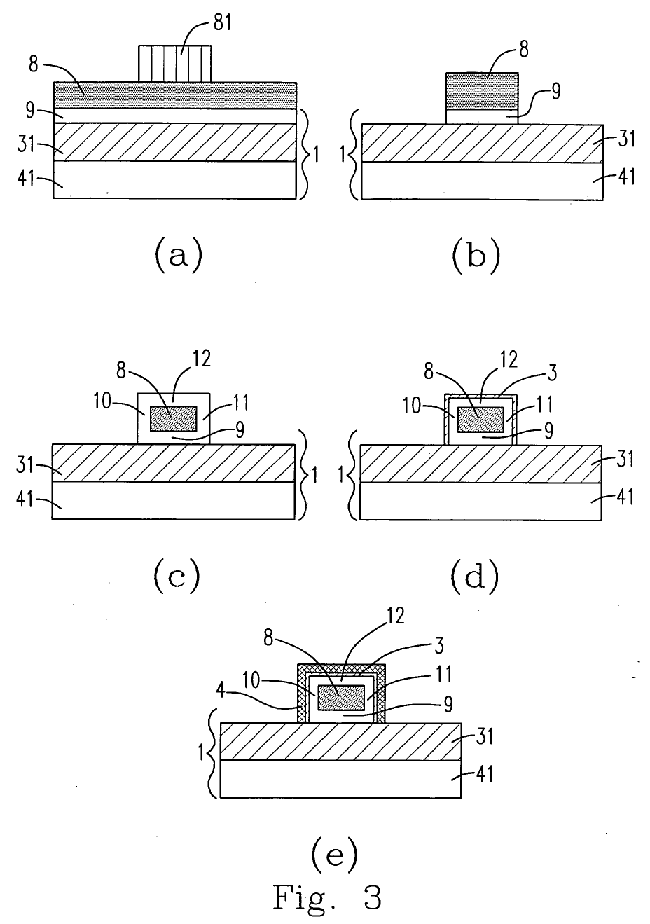

FIG. 3 shows the steps of fabrication of strained Si fin in accordance with FIG. 2. The mask 81 is used to pattern the fin-shaped structure, and therefore the SiGe layer 9 and the Si layer 8 are shaped to form isolated island as shown in FIG. 3b. A silicon layer is grown on the isolated island until the right-side, the left-side, and the top surfaces of the isolated island are covered by the silicon layer, so the SiGe body is embedded in the strained Si as shown in FIG. 3c. Then an oxide layer 3 is formed on the surface of the Si layer at an intermediate section of the fin-shaped island as shown in FIG. 3d. Finally, a poly Si layer 4 is formed on the surface of the oxide layer representing the gate electrode as shown in FIG. 3e.

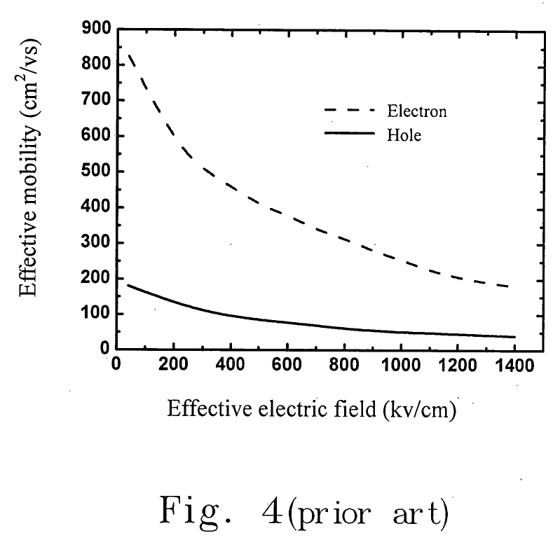

The relationship between the effective mobility of carrier in Si and effective electric field in conventional Si FinFET is shown in FIG. 4. Both electrons and holes are following the universal mobility curve.

As shown in FIG. 1, the conventional Fin Si is substituted by novel strained Si structure. The cross-sectional view of novel strained Si structure is shown in FIG. 2. Referring to FIG. 2, the numerals 13 and 16 represent the thicknesses (T₁ and T₄) of the silicon layers 9 and 12, respectively, the numerals 14 and 15 represent the widths (T₂ and T₃) of the silicon layers 10 and 11, respectively, and the numerals 17 and 18 represent the height (H) and the width (W) of the SiGe embedded body 8, respectively. When the height (H) 17 and the width (W) 18 of the SiGe embedded body are much larger than the thickness of the Si layer (T₁) 13 thereunder, the SiGe embedded body is relaxed and the surrounding Si is strained. Because mobility of strained Si is very high, operating speed of the strained Si FinFET is fast. Relaxation percentage under thermal equilibrium can be estimated by the equation: relaxation=H/(H+T₁).

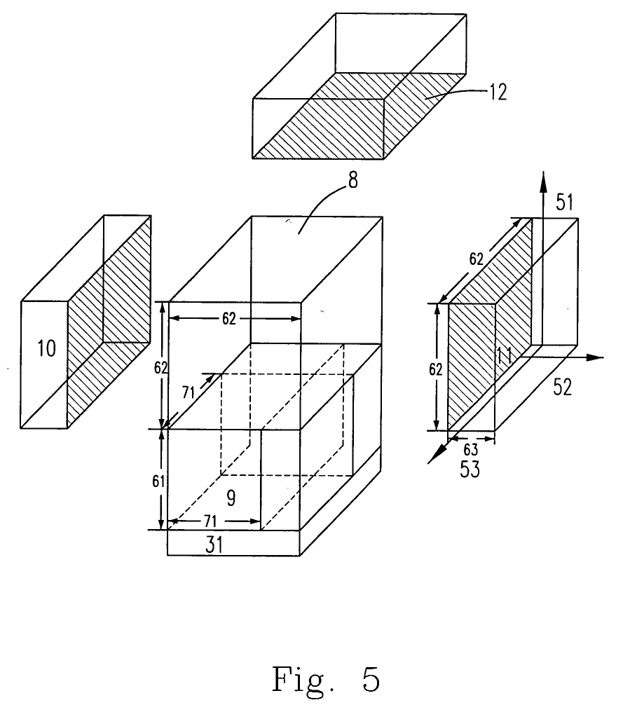

After growing the relaxed SiGe embedded body 8 on the buried silicon layer 9 of SOI, and etching the relaxed SiGe embedded body 8 and the Si layer 9 thereunder to form an island-shaped central body, Si layers 10, 11, 12 on three sides of the embedded body are grown by means of low temperature process. Therefore, the relaxation is less dependent on T₂, T₃, and T₄. Under normal design of the device having sufficiently high H (ex. H=10T₁), the SiGe embedded body is almost fully relaxed and the Si surrounding the SiGe embedded body is almost fully strained. By using the strained Si as a channel, mobility of the carrier is enhanced. The mechanism of forming strained Si and the reason for the enhancement of mobility can be illustrated by the unit cell shown in FIG. 5.

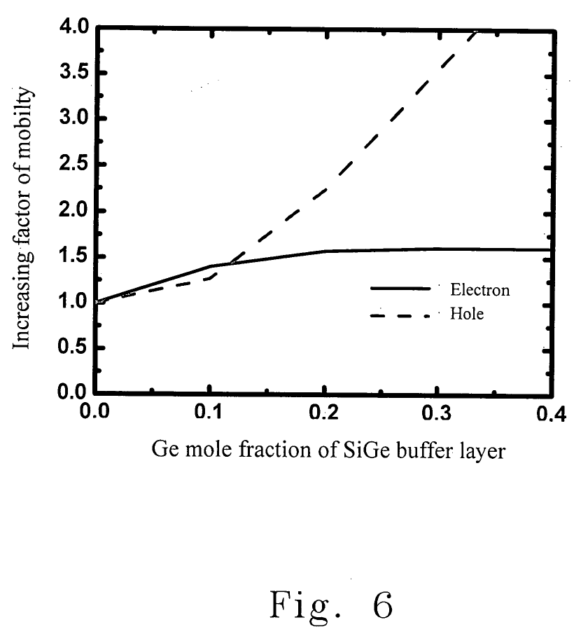

Assuming that lattice constants of the two interfaces match well and no dislocation occurs, the lattice constant parallel to the surface is almost the same as that of the material with thicker layer. If the thickness of the SiGe embedded body is of the range of 10-100 μm, the silicon layer and the oxide layer of SOI will be free slipping. (reference: G. Kastner and Gosele, “Principles of strain relaxation in heteroepitaxial films growing on compliant substrate,” J. Appl. Phys., Vol. 88, pp. 4048-4055, 2000). In this situation, the Si surrounding the SiGe embedded body is called strained Si which is subject to tensile strain. The name “tensile strain” comes from the reason that the unit cells of Si 9, 10, 11, and 12 in FIG. 5 must match four sides of the SiGe embedded body with the same lattice constant as that of the unit cells. The lattice constant of the direction parallel to direction 51 and that of the channel direction 53 are then the same as that of relaxed SiGe embedded body, and that of the direction parallel to direction 52 is the smallest. Therefore, Si 9, 10, 11, and 12 are strained Si which are subject to tensile strain and the mobility in the channel direction of four sides of SiGe embedded body is increased by strain. FIG. 6 shows the increasing factor of mobility of carrier in the strained Si surrounding the relaxed SiGe embedded body-to-mole fraction of Ge of SiGe buffer layer. The mobility is in the channel direction, and as to the calculation, one can see the reference: F. M. Bufler et al., “Hole and electron Transport in Strained Si: Orthorhombic versus biaxial tensile strain,” Appl. Phys. Lett., Vol. 81, pp. 82-84, 2002. Generally, in the channel direction of the strained Si on four sides of SiGe embedded body, 8% of strain will cause a 60% increase in electron mobility and 2.25 times the hole mobility. Using relaxed SiGe embedded body to grow strained Si requires 20% mole fraction of Ge.

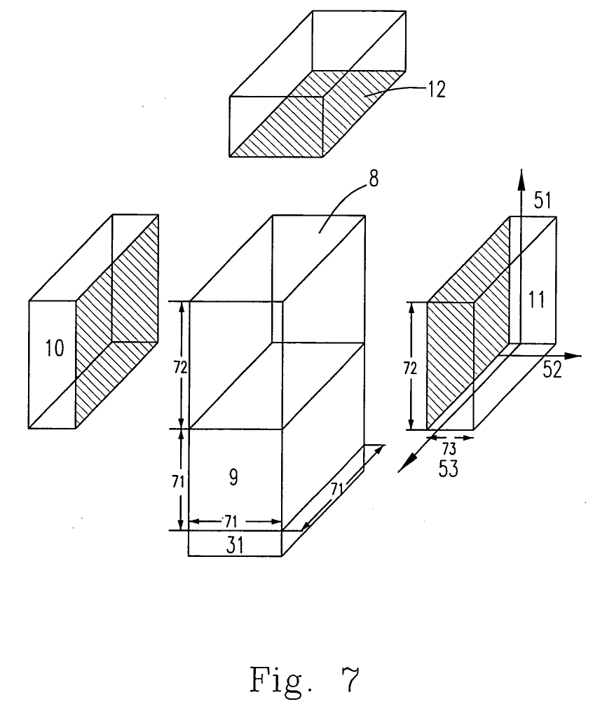

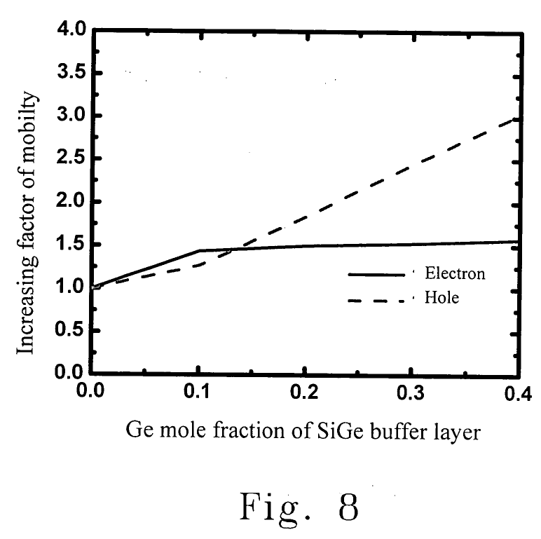

If SiGe is fully strained due to the change of growing technology, for example, with T₁ large enough or using low temperature unbalance growth, SiGe embedded body remains strained and forms tetragonal lattice. Therefore, mobility of Si on the right and left sides of the SiGe embedded body is increased. As shown in FIG. 7, the reason why it is called “orthorhombic strain” is that the unit cells of Si 10 and 11 in FIG. 5 are grown on two sides of the SiGe embedded body with different lattice constants. The lattice constant which is of the direction parallel to the direction 51 is larger, and that which is of the direction parallel to the channel direction is the same as that of the relaxed Si. The lattice constant which is of the direction parallel to the direction 52 is the smallest. Si of region 10 and region 11 are strained unit cells which are subject to orthorhombic strain; and Si of region 9 and region 12 are not strained, whose lattice constants are the same as relaxed Si. So, Si 10 and 11 are called strained Si subjected to the orthorhombic strain with increased mobility in the direction 51 and the channel direction 53 because of reduction of effective conducting mass. Si 9 and Si 12 at the bottom and top of the SiGe embedded body respectively are relaxed Si with no increase in mobility. The Si on the right and left sides of SiGe embedded body are subjected to orthorhombic tensile strain and FIG. 8 shows the increasing factor of mobility of carrier of the channel direction under that strain (reference: F. M. Bufler, “Hole Transport in Orthorhombically strained Si,” Journal of Computational Electronics, Vol. 1, pp. 175-177, 2002; Xin Wang et al., “Monte Carlo Simulation of Electron Transport in Simple Orthorhombically Strained Silicon,” J. Appl. Phys., Vol. 88, pp. 4717-4724, 2000; F. M. Bulfer et al., “Hole and Electron Transport in Strained Si: Orthorhombic versus biaxial tensile strain,” Appl. Phys. Lett., Vol.81, pp. 82-84. 2002). Generally, the strain of Si 10 and Si 11 of the channel direction in FIG. 2 will cause 1.5 times the electron mobility and 1.8 times the hole mobility when the SiGe embedded body which is of 20% Ge mole fraction is fully strained and the strained Si is grown on it. However, Si 9 and Si 12 are not subjected to strain, so the mobility is not increased. The influence of surface roughness of the Si/SiO₂ interface on mobility is not taken into consideration in FIGS. 4, 6 and 8. Generally, a rougher interface has lower mobility. According to the simulation of the reference: M. V. Fischetti, F. Gamiz, and W. Hansch, “On the enhanced electron mobility in strained-silicon inversion layers,” Journal of Applied Physics, Vol. 92, pp. 7320-7324, 2002, in order to fit the curve of effective mobility vs. effective electric field, the parameter of the roughness of the strained Si used in the simulation must be smaller than that of conventional Si. In the experiment, the mobility is indeed increased with an oxide layer. The phenomenon is obvious for electrons but is not seen for holes. It is obvious that carrier mobility in strained Si is greatly enhanced, and hence the invention, strained Si FinFET, enormously improves the speed of the FET due to the advantage of increasing mobility.

The strained Si FinFET disclosed in this invention utilizes SiGe embedded body to generate strained Si, and therefore the fin-shaped strained Si has the advantages of both strained Si FET and fin-shaped FET. The strained Si FinFET disclosed in this invention will effectively overcome the physical limitation due to the scaling down of device dimension, and hence the small and high-speed FETs can be produced.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A strained Silicon FinFET (Fin Field Effect Transistor), comprising:
a substrate;
a strained silicon in a shape of a fin island located on said substrate;
a semiconductor embedded in said strained silicon;
a dielectric layer formed on a surface of an intermediate section of said strained silicon; and
electrodes formed on said fin island and said dielectric layer.

2. The strained Silicon FinFET as claimed in claim 1, wherein said substrate is an SOI (Silicon on Insulator) substrate.

3. The strained Silicon FinFET as claimed in claim 1, wherein said semiconductor is employed for generating a strained silicon channel.

4. The strained Silicon FinFET as claimed in claim 1, wherein said semiconductor is selected from a group consisting of a SiGe alloy, a SiGeC alloy, a SiC alloy, and a material which is suitable for producing strained silicon.

5. The strained Silicon FinFET as claimed in claim 1, wherein said surfaces of said intermediate section of said strained silicon covered by said dielectric layer comprise left side, right side, and top side surfaces of said intermediate section.

6. The strained Silicon FinFET as claimed in claim 1, wherein said dielectric layer is one of an oxide layer and a high dielectric constant (high K) layer.

7. The strained Silicon FinFET as claimed in claim 6, wherein said high dielectric constant (high K) layer is selected from a group consisting of HfO₂, Si₃N₄, and Al₂O₃.

8. The strained Silicon FinFET as claimed in claim 1, wherein said electrodes are a gate electrode formed on a surface of said dielectric layer, a source electrode formed on one terminal of said strained silicon; and a drain electrode formed on the other terminal of said strained silicon.

9. The strained Silicon FinFET as claimed in claim 7, wherein said gate electrode is selected from a group consisting of an n⁺ doped polysilicon gate electrode, a p⁺ doped polysilicon gate electrode, an n⁺ doped poly SiGe gate electrode, a p⁺ doped poly SiGe gate electrode, and a metal gate electrode.

10. The strained Silicon FinFET as claimed in claim 1, wherein said strained silicon has conducting carriers.

11. The strained Silicon FinFET as claimed in claim 10, wherein said conducting carrier is one of an electron and a hole.

12. A method for manufacturing a strained Silicon FinFET, comprising:
(a) providing a substrate comprising a first silicon layer thereon;
(b) forming a semiconductor layer on said substrate;
(c) forming a fin-shaped island;
(d) forming a second silicon layer on a surface of said fin-shaped island;
(e) forming a dielectric layer on surfaces of said second silicon layer at an intermediate section of said fin-shaped island; and
(f) forming electrodes on said dielectric layer and said fin-shaped island.

13. The method for manufacturing the strained Silicon FinFET as claimed in claim 12, wherein said substrate is an SOI (Silicon on Insulator) substrate.

14. The method for manufacturing the strained Silicon FinFET as claimed in claim 12, wherein said semiconductor is employed for generating a strained silicon channel.

15. The method for manufacturing the strained Silicon FinFET as claimed in claim 12, wherein said semiconductor is selected from a group consisting of a SiGe alloy, a SiGeC alloy, a SiC alloy and a material which is suitable for producing strained silicon.

16. The method for manufacturing the strained Silicon FinFET as claimed in claim 12, wherein said fin-shaped island comprises said semiconductor layer and said first silicon layer.

17. The method for manufacturing the strained Silicon FinFET as claimed in claim 12, wherein the method for forming the fin-shaped island is etching.

18. The method for manufacturing the strained Silicon FinFET as claimed in claim 12, wherein said surface of said fin-shaped island covered by said second silicon layer is the whole surface of said fin-shaped island.

19. The method for manufacturing the strained Silicon FinFET as claimed in claim 12, wherein said dielectric layer is one of an oxide layer and a high dielectric constant (high K) layer.

20. The method for manufacturing the strained Silicon FinFET as claimed in claim 19, wherein said high dielectric constant (high K) layer is selected from a group consisting of HfO₂, Si₃N₄, and Al₂O₃.

21. The method for manufacturing the strained Silicon FinFET as claimed in claim 12, wherein said surfaces of said second silicon layer covered by said dielectric layer comprise left side, right side, and top side surfaces of said second silicon layer.

22. The method for manufacturing the strained Silicon FinFET as claimed in claim 12, wherein said electrodes are a gate electrode formed on a surface of said dielectric layer, a source electrode formed on one terminal of said strained silicon; and a drain electrode formed on the other terminal of said strained silicon.

23. The method for manufacturing the strained Silicon FinFET as claimed in claim 22, wherein said gate electrode is selected from a group consisting of an n⁺ doped polysilicon gate electrode, a p⁺ doped polysilicon gate electrode, an n⁺ doped poly SiGe gate electrode, a p⁺ doped poly SiGe gate electrode, and a metal gate electrode.
